(19) United States
(12) Patent Application Publication
(10) Pub. No.: US 2005/0242343 A1
(43) Pub. Date: Nov. 3, 2005

(54) Organic electronic circuit with functional interlayer, and method for making the same

(75) Inventors: Niclas Edvardsson, Sturefors (SE); Isak Engquist, Linkoping (SE); Mats Johansson, Linkoping (SE)

Correspondence Address: BIRCH STEWART KOLASCH & BIRCH, PO BOX 747, FALLS CHURCH, VA, 22040-0747, US

(73) Assignee: Thin Film Electronics ASA

(21) Appl. No.: 11/115,242

(22) Filed: Apr. 27, 2005

(30) Foreign Application Priority Data
Apr. 28, 2004 (NO) 20041733

(51) Int. Cl. H01L 29/08

(52) U.S. Cl. 257/40

(57) ABSTRACT

An organic electronic circuit (C) with improved performance, particularly at elevated temperatures, comprises an organic electret or ferroelectric material (2) provided between a first electrode (1a) and a second electrode (1b). A cell with a capacitor-like structure is defined in the organic electret or ferroelectric material (2) and can be accessed electrically directly or indirectly via the electrodes. At least one functional interlayer (3a; 3b) is provided between one of the electrodes (1a; 1b) and the organic electret or ferroelectric material (2). The interlayer material is inorganic, non-conducting and substantially inert relative to the organic electret or ferroelectric material (2) in general. Typically the interlayer (3) is inert relative to the organic electret or ferroelectric material (2) particularly when the latter is a fluorine-containing material. A plurality of circuits (C) is used for forming a matrix-addressable array.—The interlayer is deposited as molecular species from a source of functional interlayer material without dissociation of individual interlayer molecules.

The present invention concerns an organic electronic circuit comprising an organic electret or ferroelectric material located between a first electrode and a second electrode, whereby a cell with a capacitor-like structure is defined in the organic electret or ferroelectric material and can be accessed electrically directly or indirectly via the electrodes.

During recent years, non-volatile data storage devices have been demonstrated where each bit of information is stored as a polarization state in a localized volume element of an electrically polarizable material. A material of this kind is called an electret or ferroelectric material. Formally ferroelectric materials are a subclass of electret materials and capable of being spontaneously polarized to either a positive or negative permanent polarization state. By applying an electric field of appropriate polarity, it is moreover possible to induce a switching between the polarization states. Non-volatility is achieved since the material can retain its polarization even in the absence of externally imposed electrical fields.

However, there are some phenomena related to ferroelectric and electret materials that have detrimental influence on performance of circuits and devices that employ these materials.

Ferroelectric materials that are subjected to electrical field stresses of repeated nature, e.g. numerous polarization switches, suffer fatigue, i.e. deterioration of the electrical response required for reliable operation of the device employing the ferroelectric material. In a ferroelectric memory cell this manifests as a decrease of polarization, thus less charges released that may be used in detection of the polarization state of the cell. Consequently fatigue will ultimately render the device useless. There will be a number of switches that a device can sustain until fatigue becomes critical.

Another problem is disturb, which is related to loss of polarization in a electret or ferroelectric memory cell which has been prepared in a given polarization state and then is exposed to disturbing voltage pulses with a polarity in the opposite direction (i.e. a direction tending to polarize the cell in a sense opposite to that where it had been prepared). Even when the disturbing voltages are well below what is required to completely switch polarization state, repeated exposure may cause the material to undergo partial switching leading to a loss of polarization.

Ferroelectric materials that are allowed to remain in a polarization state for a period of time are subjected to imprint. It manifests as a change in the switching properties whereby there is a decrease in the electrical field perceived by the material when an opposite-polarity electrical field is applied to switch the polarization direction into the opposite from where the material has resided during the imprinting period. In other words, the polarization has a tendency to become stuck in the direction in which it has been allowed to reside for some time.

Generally, one can say that these problems are related to performance deterioration in circuits and devices that utilize and take advantage of ferroelectric and electret materials. The deterioration of performance pertains to the degree of polarization and the possibility to alter and detect the polarization in a desirable manner.

As described in patent applications previously filed by the present applicant, e.g. international published application WO99/12170, organic-based and in particular polymeric ferroelectric materials provide considerable advantages for use in memory and/or processing devices as compared to their inorganic counterparts. However, the problems mentioned above also do occur in organic-based electret or ferroelectric materials, which if not solved will cause obstacles for commercialization.

Typically a memory device with memory cells using electret or ferroelectric materials as memory material has a capacitor-like structure with a layer of the memory material stacked between two layers of electrodes. It has previously been shown that performance of ferroelectric memory cells may be improved by introducing so called functional materials in the interface between electrode and memory material of the cells. In international published application WO03/044801 assigned to the present applicant, functional materials are disclosed that may be incorporated in the electrode material, or as a separate interlayer between the electrode and the memory material. Groups of conducting functional materials are presented, e.g. such that are conducting and capable of physical and/or bulk incorporation of atomic or molecular species contained in either the electrode material or the memory material. WO03/044801 addresses the problem that exchange of for instance ionic species between the electrodes and the memory material, not only may be detrimental for both, but in addition also may have adverse effect on the fatigue resistance of the memory cell.

The name “functional” emphasize that a functional interlayer shall have a range of functions. Not only shall the functional interlayer prevent deleterious chemical reactions between the electrodes and the memory material, another function of the interlayer may for instance be to provide protection towards physical damage that can occur during manufacturing, for example during metal deposition of the electrodes. Another example of a function of the interlayer is to provide efficient electrical coupling between electrode and memory material.

In the prior art some organic interlayers have been proposed. Organic materials have some disadvantages when it comes to manufacturing in a traditional silicon based manufacturing environment. Adaptation is slower and more complicated when new types of materials are introduced and have to co-exist with existing technologies and materials.

Furthermore solutions presented in the prior art typically show instable temperature dependencies where the deterioration of performance increases at elevated temperatures. This makes it hard to meet requirements on circuits and devices that are used in a range of temperatures.

Even though prior art teaches the use of various types of functional interlayers for improved performance, there is still need for further improvements. In particular there is a need for improvement for memory devices that are close to reach commercialization, viz. circuits and memory cells with organic electret or ferroelectric materials that contains fluorine, such as VDF-based polymers like PVDF, P(VDF-TrFE) etc.

It is therefore a major object of the present invention to present a memory circuit with interlayers that has improved performance.

It is also an object to present circuits with interlayers that show improved and temperature stable performance in an interval of temperatures.

The above objects as well as further advantages and features are realized with a circuit according to the present invention in which at least one inorganic functional interlayer is provided between the at least one of the electrodes and the organic electret or ferroelectric material, ands that at least one functional interlayer is a non-conducting and substantially inert material relative to the organic electret or ferroelectric material generally. In a preferred embodiment of the present invention a plurality of such circuits forms memory circuits of a matrix-addressable array, that the cells of the memory circuits form distinct portions in a global thin-film layer of the organic electret or ferroelectric material, that the first and second electrodes form portions of first and second electrode means respectively, each electrode means comprising a plurality of parallel strip-like electrodes wherein the electrodes of the second electrode means are oriented at an angle, preferably orthogonally, to the electrodes of the first electrode means, and that the organic electret or ferroelectric global thin-film layer is sandwiched therebetween, such that the memory cells of the memory circuits are defined in the thin-film global layer at the crossings of respectively the electrodes of the first electrode means and the electrodes of the second electrode means, whereby the array of memory circuits is formed by the electrode means and the global layer of the memory material, the memory cells realizing an integrated passive matrix-addressable electret or ferroelectric memory device wherein the addressing of respective memory cells for write and read operations take place via the electrodes in suitable connection with external circuitry for driving, control and detection.

The above objects as well as further advantages and features are also realized according to the present invention with a method for manufacturing the organic electronic circuit of the present invention, the method being characterized by depositing molecular species for the functional interlayer from a source of functional interlayer material without dissociation of individual molecules forming the functional interlayer.

Yet further advantages and features of the present invention shall be apparent from the appended dependent claims.

The invention shall now be described in more detail, with reference to preferred embodiments and in conjunction with the appended drawing figures, of which

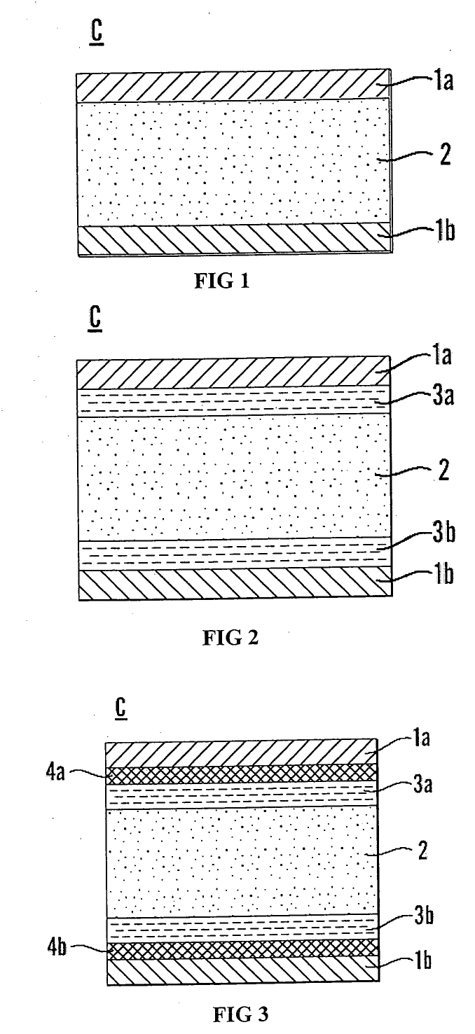

FIG. 1 shows a generic memory circuit of relevance to the present invention, representing e.g. an elementary memory cell in a data storage device as disclosed in prior art,

FIG. 2 a memory circuit according to a first embodiment of the present invention,

FIG. 3 a memory circuit according to a second embodiment of the present invention,

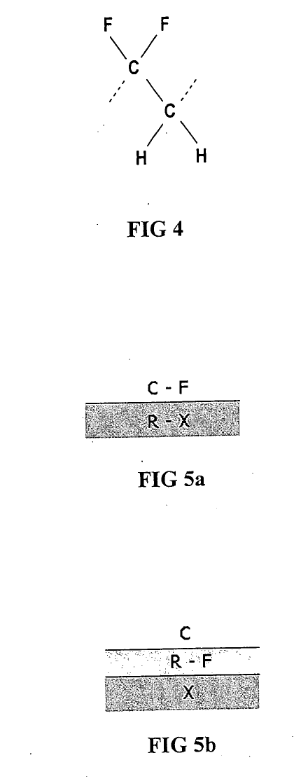

FIG. 4 a VDF bond of a polymeric chain,

FIG. 5a an example of a non-reactive situation between a binary ceramic interlayer and a electret or ferroelectric material with a carbon-fluorine bond,

FIG. 5b an example of a reactive situation, where a metal from the ceramic has dissociated and formed an undesired metal fluoride with fluorine from the electret or ferroelectric material,

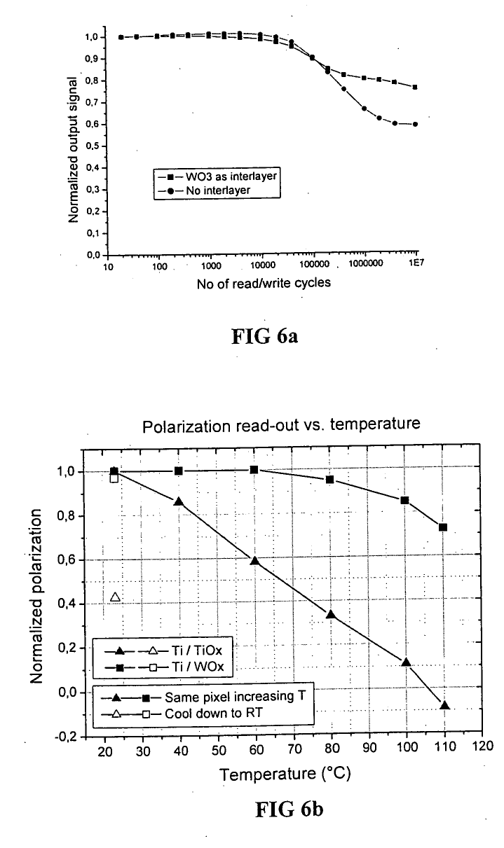

FIG. 6a an example of fatigue resistance improvements when using tungsten oxide as an interlayer according to the invention,

FIG. 6b an example of temperature dependency where an interlayer of tungsten oxide performs better than an interlayer of titanium oxide,

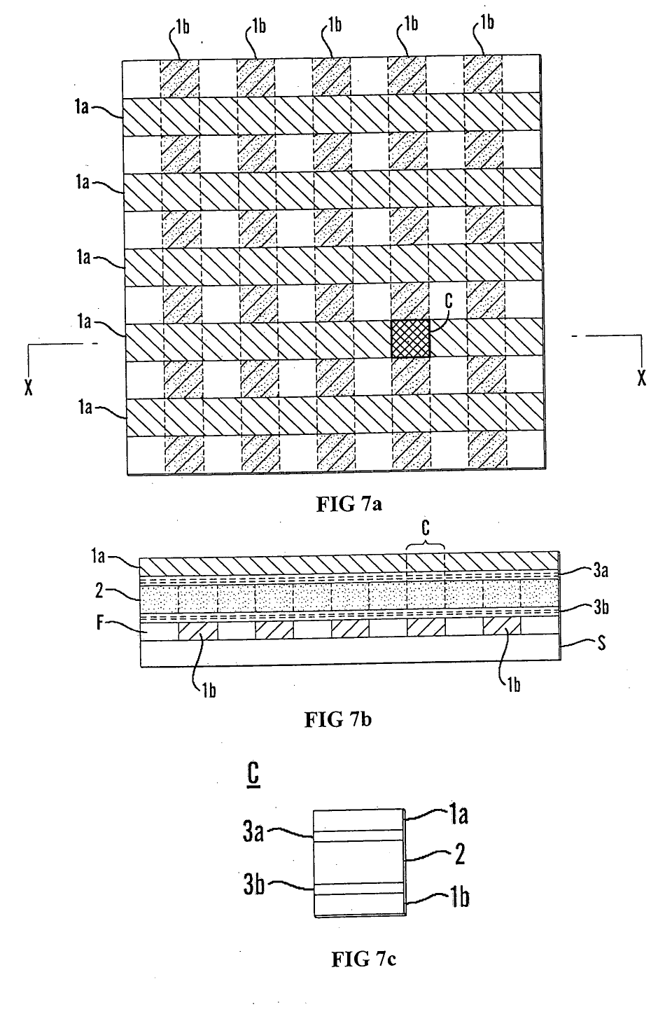

FIG. 7a a plan view of a matrix-addressable memory device comprising memory circuits according to present invention,

FIG. 7b a cross section of the device in FIG. 7a taken along the line x-x,

FIG. 7c detail of a memory circuit of the device in FIG. 7a and corresponding to the embodiment in FIG. 2.

The present invention is generally based on introducing into an organic electronic circuit that requires improved performance and temperature stability, at least one inorganic functional interlayer to a capacitor-like cell comprising an organic electret or ferroelectric material located between two electrodes. The functional interlayer is situated between at least one of the electrodes and the organic electret or ferroelectric material, typically interfacing both. The functional interlayer is providing electrical coupling between the electrode and the organic electret or ferroelectric material while separating them physically, typically to prevent reactions between the electrode and the organic electret or ferroelectric material. In addition to this, an important attribute is that the interlayer itself is chosen to be reluctant for undesired reactions with reactive parts of the organic electret or ferroelectric material, i.e. the interlayer is substantially inert relative to the organic electret or ferroelectric material. In particular shall the functional interlayer be reluctant to dissociate and react with fluorine from the organic electret or ferroelectric material. To further reduce the probability for such reactions, the interlayer molecules are disposed without dissociation from a source of functional interlayer materiel to form the interlayer in the organic electronic circuit. In the description to follow, the invention will be disclosed in further detail to provide the person experienced in the art with sufficient means to take advantage of the invention.

In conjunction with the present invention the inventors undertook extensive investigations into the causes of performance deterioration in organic electret or ferroelectric materials employed in capacitor-like memory circuits for data storage and processing applications, both in circuits without interlayers as shown in FIG. 1, and also to circuits with interlayers as shown in FIG. 2. This applies to the prior art circuit shown in FIG. 1, wherein an electrode ferroelectric material 2 is sandwiched between electrodes 1a, 1b. As will be seen the memory circuit C with first and second electrodes 1a, 1b directly or indirectly interfacing the electret or ferroelectric material 2, which e.g. may be polymer memory material sandwiched between two electrodes in a parallel-plate capacitor-like structure. In case of circuits with interlayers 3a; 3b, at least one such interlayer has been located between one of the electrodes 1a; 1b and the organic electret or ferroelectric material 2.

Although claimed to be generally applicable for organic and polymeric electret and ferroelectric materials, the subsequent discussion shall primarily treat organic ferroelectric materials containing fluorine, in particular VDF containing materials with emphasis on PVDF and its co- and/or ter-polymers with TrFE and/or TFE. This has been done in order to provide focus and concreteness to the presentation and to encompass classes of materials that appear of particular relevance for future devices of interest.

Based on theoretical and experimental findings in the search of materials providing improved performance, the inventors have found a factor in the performance deterioration that is far more important than previously believed. It is a consequence of reactions taking part between the interlayer material itself and the organic electret or ferroelectric material that results in undesirable interface regions and detrimental properties. In the present applicant's WO03/044801, it is stated that a functional material shall be “chemically compatible” with regard to both the electrodes and the organic electret or ferroelectric material, but there is no specific definition of such materials. Instead it is implied that this is solved by any interlayer material that is known to be more stable and non-reactive than the electrode material in relation to the organic electret or ferroelectric material. Prior art focus on prevention of reactions between the electrodes and the organic electret or ferroelectric material, but pays only superficial attention to reactions between the interlayer and the organic electret or ferroelectric material. Prevention of reactions between the electrodes and the organic electret or ferroelectric material of course still is an important factor, but for further improvements the inventors have found that there must be a judicious selection of functional interlayer material with purpose to reduce undesired reactions in the interface between the functional interlayer and the organic electret or ferroelectric material.

For example, in the prior art, titanium carbide (TiC) is proposed as an interlayer material of special interest since titanium is a common electrode material in circuits of today. Titanium carbide is considered chemically stable in regard of prior knowledge, which is also true in general but not necessarily true relative other materials. By comparing the bonding energy of titanium carbide with a) the bonding energy of the most reactive part in the organic electret or ferroelectric material, for example fluorine in a VDF bond, and b) with the bonding energy of the most stable fluoride that may be formed, here TiF₄, it is revealed that formation of titanium fluoride is thermodynamically favourable, i.e. there is a substantial risk that more and more reactions where TiF₄ is formed will occur over time. This effect will typically be reinforced during operational circumstances that involve additional energy, e.g. during applied electrical fields, polarization switching and increased temperatures. In other words, TiC should not be chosen as an interlayer material in a situation where high performance is required by avoiding reactions that cause formation of a “dead layer”, i.e. a non-functional interface, of titanium fluoride between the interlayer material and the organic electret or ferroelectric material. Instead materials shall be chosen where the difference in bonding energies makes reactions less probable, i.e. materials with a significant threshold to overcome before reactions may occur and where the formation of the metal fluoride is not as favourable from an energetic point of view.

Calculations to determine how probable a certain reaction is, will typically require some simplifications. A thermodynamic approach like above typically will assume thermodynamic equilibrium and bulk contact of materials. However, it has shown that metrics provided by such an approach do not have to be correct in terms of absolute numbers as long as they provide a reasonable estimation and are relatively correct, i.e. as long as the calculations provide means to determine which material in a group of materials that is the best choice. In a practical and complex multi-variable situation there will always be uncertainties that cannot be foreseen and there are no “perfect” materials. Under such circumstances it is only reasonable to speak about reactions that can occur, for example reactions with fluorine from the organic electret or ferroelectric material. The best thing that can be done is to limit the extent of such reactions by a selection of an interlayer material that is as reluctant as possible to dissociate and bond with the most reactive part, viz. in this example the fluorine, which typically has to dissociate first. For a given organic electret or ferroelectric material, persons skilled in the art shall be able to identify the dominant reactive part, which in case of a reaction with the interlayer material may cause some unintended and unwanted compound with detrimental properties. An example of a reactive part is fluorine in a polymeric VDF bond as in the case of PVDF-based ferroelectric materials. A general consequence from this is that the interlayer material of interest shall be substantially inert relative to the electret or ferroelectric material. However, even though generally inert, there may be situations where specific bonding and/or reactions are desirable between an interlayer and the electret or ferroelectric material, but of course not in a detrimental manner and without formation of “dead layers”. Typically such a situation require some specific adaptation of the interlayer, i.e. that the interlayer is adapted to participate in a specific chemical reaction or bonding with one or more consecutive components of the adjoining electret or ferroelectric material. Or that the interlayer is adapted to participate in a specific chemical reaction with reactive species that are generated in the electret or ferroelectric material during operation of a circuit that comprises the relevant materials. While being defined as reluctant for detrimental reactions with the organic electret or ferroelectric material, the interlayer material at the same time of course has to meet other requirements, such as on functionality, compatibility in a specific production environment etc.

Moreover; in many prior art circuits, the performance deterioration show strong temperature dependency, something which is undesirable since performance typically has to be secured in an interval of temperatures. For example, most circuits shall at least be operable in a significant temperature window around and above room temperature, e.g. in the range 10-80° C. At any temperature in the interval, such circuits shall be able to provide a sufficiently large polarization as to ensure reliable operation. Further, the circuits shall be able to sustain a number of switches limited by fatigue that is equal to or higher than the number determined by requirements on the device employing the circuit, e.g. a memory device. However, most known circuits show a temperature dependency where the polarization tend to decrease at elevated temperatures and where the number of switches when fatigue becomes critical decreases at higher temperatures. This makes it hard to accomplish circuits that have to meet demanding requirements. Within the scope of the present invention, this is explained by that higher temperatures adds energy and increases the probability for reactions in the interface between the interlayer and the organic electret or ferroelectric material. If the threshold for a reaction to take part is low already at relatively low temperatures, an increase in temperature may push the number of reactions over a critical limit and the performance deteriorates. The present invention teaches that the solution is to start with a higher threshold, i.e. to select an interlayer material that is particularly reluctant to react with reactive species in the organic electret or ferroelectric material, i.e. as in the case of PVDF, an interlayer material that has low propensity to dissociate and react with fluorine that dissociate from a polymeric VDF bond in the organic electret or ferroelectric material.

Attributes which may be provided in a purpose-built functional interlayer is low electrical resistance or large capacitance in the frequency regions of interest, which effectively couples the electrode to the electro-active organic material. The desired electrical properties relates to the fact that voltage controlled cells in capacitor-like structures are vulnerable to build-up of “dead” layers. The “dead” layers may for example consist of chemical reaction products that are electrically insulating and have a low dielectric constant. A “dead” layer that represents a low capacitance in series with the memory cell will lead to a reduced proportion of the applied cell voltage being brought to bear on the memory substance in the cell, resulting in poorer performance. Furthermore, in memory cells containing memory material of the electret or ferroelectric type, the “dead” layer prevents compensating charges from reaching the surface of the memory material, and large depolarization fields may remain inside the memory material, which contribute to a destabilization of the polarization state of the memory cell. Interlayers with low electrical resistance, i.e. conducting interlayers, are presented in the above-mentioned WO03/044801. The present invention will therefore focus on non-conducting interlayers. In this international published application WO03/044801 the focus is on extending the electrical properties of the electrodes to the interlayer. The materials are conducting to be able to provide bulk incorporation capabilities. However, even though bulk incorporation capability is one feasible way, it is not by any means the only way to provide an efficient functional interlayer. There are non-conducting inorganic materials with desirable functions according to the present invention that advantageously may be used, even though these materials do not have the bulk incorporation capabilities as disclosed in WO03/044801. Typically non-conducting materials in interlayers have to be dielectric with a relative permittivity that is about the same or higher than the relative permittivity of the organic ferroelectric and/or electret material. This is in order to keep any voltage drop over the interlayer at a reasonable low level. In memory devices of relevance today, the required dielectric properties shall be maintained for frequencies up to 1 MHz.

The present invention is focusing on inorganic interlayer materials. Today an inorganic interlayer material is considered advantageous in fabrication and is believed to lead to faster commercialization. This is due to the fact that most of the existing manufacturing environments are adapted to inorganic technologies.

Typical electrode materials used in conjunction with the present invention are conductors of metal such as Al, Ti, Cu, Pt, Au, Pd etc. Various conducting composites are also possible. The electrodes may further consist of conducting functional materials as disclosed in WO03/044801, for example TiN. One should pay attention to the risk of detrimental reactions between the electrode material and the interlayer. However, in many situations the choice of electrode material may be restricted by requirements set on other parts of a device employing circuits of the present invention. In a practical situation this means that the choice of electrode material often is delimited.

According to an embodiment of the invention, an inorganic interlayer is prepared for contacting a organic electret or ferroelectric material wherein the interlayer material is substantially inert, i.e. has low probability to react with reactive parts of the organic electret or ferroelectric material, typically fluorine in a polymeric VDF bond. This is achieved by judicious selection of interlayer materials for use in a capacitor-like structure comprising at least two conducting electrode layers with the organic electret or ferroelectric material layered in between and one or more functional interlayers between at least one of the electrodes and the organic electret or ferroelectric material.

Desired functionality of the interlayer structure are:
i) Relative permittivity being -equal or larger than the relative permittivity of the organic electret or ferroelectric material.
ii) Reluctance, low probability, to react with the most reactive parts of the organic electret or ferroelectric material.
iii) Barrier activity against migration of species between electrodes and the organic electret or ferroelectric material.

The relatively high relative permittivity assures that none or only a small and non-significant amount of switching voltage and related electrical field is applied over the interlayer. The reluctance to react with e.g. fluorine bond in the organic electret or ferroelectric material preserves integrity and functionality of the interlayer and the organic electret or ferroelectric material. The barrier properties provide protection against detrimental reactions between electrodes and the organic electret or ferroelectric material.

FIG. 2 shows a preferred embodiment of an organic electronic circuit C according to the invention, where two interlayers 3a, 3b provide the desired functionalities. The interlayers 3a, 3b here prevent direct contact between the electrodes 1a, 1b and the organic electret or ferroelectric material 2. The interlayers are located one at each side of the organic electret or ferroelectric material 2 and each interlayer is being provided in a layer with a thickness that assures coverage of at least the common surface between the electrode and the organic electret or ferroelectric material.

FIG. 3 shows another preferred embodiment of an organic electronic circuit C according to the invention, wherein two interlayers 3a, 4a and 3b, 4b are provided on each respective side of the organic electret or ferroelectric material 2. Here the desired functionality of the interlayers may be split between the two interlayers on each side. Obviously, the interlayers 3a, 3b in contact with the organic electret or ferroelectric material 2 shall be the ones that are substantially inert relative to the organic electret or ferroelectric material 2. However, the barrier activity may partly be provided by the interlayers 4a, 4b in contact with the electrodes. Typically the interlayers 4a, 4b at the electrodes will be conductive and an extension of the electrodes, as for example as presented in the prior art application WO03/044801.

Variants of the embodiments presented in FIG. 2 and FIG. 3 may for example include circuits with different combination of the numbers of interlayers on each side, e.g. one/zero or two/one. It is also possible with more than two interlayers on each side of the organic electret or ferroelectric material. An asymmetric approach may be desired in situations where different electrode materials are used on each side, for example if there is a non- or low-reactive electrode on only one side, or if the methods of deposition of the layers in the circuit motivate a different approach depending on which side of the organic electret or ferroelectric material an interlayer is located. For example, in a stacked structure, the deposition of a top electrode, or top interlayer, will typically require some special attention due to the risk of damage of the already deposited layer of organic electret or ferroelectric material.

The low-reactive property of a functional material according to the invention shall now be exemplified in some detail. For simplification and reasons of convenient presentation a group of binary ceramic materials are selected as candidates for a non-reactive interlayer material. Fluorine in a polymeric VDF bond, as illustrated in FIG. 4, is further assumed to be the dominant and most reactive part in the organic electret or ferroelectric material. The situations in which a reaction takes place or not, are illustrated by FIG. 5a and 5b. In the non-reactive situation in FIG. 5a, R—X is the binary interlayer material where R is a metal and X may represent O (oxides), N (nitrides), C (carbides), B(borides) etc. In FIG. 5b where a reaction has taken part, the interlayer molecule has dissociated, the fluorine (F) has broken from the VDF bond, and the metal and the fluoride has formed a non-functional and undesired “dead”-layer (R—F). Evaluation of which interlayer materials that are the most reluctant can for example be done by calculating differences (D) in enthalpies (Δ_{f}H⁰) according to the approximate formula:
D=Δ_{f}H⁰(RFₘ)−(m*Δ_{f}H⁰(CF)+1/n*Δ_{f}H⁰(RₙX)) (1)

The number of bonds involved is essential, here m denotes the number of fluorine (F) atoms in the most stable metal fluoride (RFₘ) that may form, and n denotes the number of X-bonds per metal atom in the interlayer ceramic material (RₙX). Using the above thermodynamic approach with enthalpies has the advantage that many inorganic materials has the bond strengths tabulated, however, the strength of the carbon-fluoride (C—F) bond in a VDF chain as in the case of PVDF typically needs to be estimated by a person skilled in the art. For example, dividing bond strength for a gaseous carbon-fluoride molecule with the number of C—F bonds results in a reasonable estimation of 200 kJ/mol for the carbon-fluoride (C—F) bond in a polymeric VDF chain. Positive and high numbers D from the formula (1) indicates materials that are reluctant to react, i.e. low propensity for reactions. In table 1, some results are listed based on calculations according to this example.

TABLE 1
Some results based on enthalpy calculations for binary ceramics

| D (kJ/mol) | Material |
|---|---|
| 700-900 | Iridium oxide (IrO₂) |
| 500-700 | |
| 300-500 | Molbydenum oxide (MoO₃), Vanadium oxide |
| | (V₂O₂) |
| 100-300 | Tungsten oxide (WO₃), Niobium oxide (Nb₂O₅) |
| (−100)-100 | Titanium oxide (TiO₂), Tantalum oxide (Ta₂O_{2),} |
| | Halfnium oxide (HfO₂), Copper oxide (Cu₂O) |
| (−300)-(−100) | Molybdenum boride (Mo₂B₅) |
| (−500)-(−300) | Chromium boride (CrB₂) |
| (−700)-(−500) | Titanium nitride (TiN), Titanium carbide (TiC), |
| | Aluminium nitride (AlN), Tantalum boride (TaB₂) |

Approaches similar to the above may be used to define various interlayer materials that are substantially inert relative to organic electret or ferroelectric materials of relevance.

Some examples of functional materials which can be used in the memory circuit according to the invention shall now be given, with explicit descriptions of functional interlayers that are suited for use with fluorine-containing memory materials. As previously mentioned, this emphasis is based on the fact that certain fluorine-containing polymeric ferroelectrics, in particular PVDF and copolymers of VDF and TrFE show particular promise as memory materials in future data storage devices. It is also a fact that fluorine-containing memory materials pose exceptional challenges due to the mobility and chemical aggressiveness of fluorine.

### EXAMPLE 1

### Metal Oxides as Interlayer Material

By comparisons similar to the above, it is revealed that among binary ceramics, stable metal oxides generally are preferred over what is considered to be stable metal nitrides, borides etc. This is due to the fact that the bonding energy for the oxides in general are higher. Non-conducting metal oxides with high oxidation numbers (e.g. W, Ta, Mo, Nb, V) are of particular interest in conjunction with fluorine containing ferroelectrics like PVDF. The reason for this is that high oxidation numbers require many carbon fluorine (C—F) bonds to break, i.e. that m in the formula (1) given above is high.

The impact on performance using some interlayer metal oxides is shown in FIGS. 6a and 6b. In 6a the performance of an interlayer of tungsten oxide (WO₃) in a capacitor-like memory cell of the type presented in conjunction with the embodiment of FIG. 2 is compared to a corresponding situation without interlayers. In FIG. 6b the performance of an interlayer of titanium oxide (TiOₓ, mainly TiO₂) is compared to one of WO₃. In both figures P(VDF-TrFE) is used as organic ferroelectric memory material and titanium as electrode material. Apart from the interlayer, the structures for the memory cells used in FIG. 6a and 6b are as similar as possible. WO₃ as interlayer shows improved performance, here illustrated by improved fatigue resistance compared to a cell with no interlayer. A WO₃ interlayer cell further shows improved behaviour over the TiO₂ cell, both in terms of number of fatigue cycles at a fixed temperature (not illustrated) and in terms of temperature stability as shown in FIG. 6b. The results are in line with the expectations based on the reluctance to react with fluorine in the polymeric memory material. Note that in both figures the output signal, which measures the degree of remanent polarization, has been normalized for each curve separately. For each curve the initial value of the output signal has been used in the normalization.

A WO₃ interlayer has some further advantages due to the fact that tungsten, in the form of tungsten plugs, is a material that already has been introduced and is used in fabrication. This should be beneficial for manufacturing adaptation and thus lead to faster commercialization of electronic devices employing organic circuits according to the present invention.

### EXAMPLE 2

### Ternary Ceramics as Interlayer Material

Many ternary ceramics, in particular ternary oxides, like for example SiZrO₄, BaTiO₃, and MgTiO₃, show reaction reluctance even higher than many of the binary metal oxides. Of same reason as given in example 1, ternary ceramics with metals having high oxidation number is of particular interest.

The thickness of the interlayers may vary depending on the material. Typically the thickness shall provide a sufficiently dense coverage to prevent contact between electrode material and the organic electret or ferroelectric material. However, different interlayer thicknesses may be required not only due to different interlayer materials. Other factors that may influence the thickness are the type of surface on which the interlayer are deposited (its roughness etc.), how the layer is deposited, how subsequent layers are deposited on top of the interlayer and other manufacturing or environmental related circumstances. In the case of WO₃ as interlayer, it has for example been found that the layer deposited on the bottom electrode advantageously may be thinner than the layer deposited on a P(VDF-TrFE) ferroelectric material. A WO₃ layer has advantages, but is of course not “perfect”. There will for example always be a small voltage drop induced over a WO₃ layer and in regard to this it is desirable to use an interlayer that is as thin as possible, but a thin interlayer is more sensitive to imperfections in the surface. An imperfect surface may allow electrode material to come in contact and react with the organic electret or ferroelectric material, e.g. via diffusion. A thick layer, that initially has some disadvantage over a thin layer, may therefore prove better in operation since there will be less probability for such reactions, which over time may cause higher voltage drop and damage ferroelectric properties. In a cell with WO₃ interlayers, the thicknesses advantageously are in the range 25-1000 Å.

FIG. 7 shows a situation where memory circuits C of the present invention are employed as memory circuits in a matrix addressable array of such circuits. Here they constitute a passive matrix-addressable memory device as shown in plan view in FIG. 7a and in cross section taken along line X-X in FIG. 7b. The organic electret or ferroelectric material 2 here is the memory material of the circuit. The memory device is termed a passive matrix device since there are no switching transistors connected to a memory circuit for switching a memory cell C on and off in an addressing operation. This would imply that the memory material of the memory cell C in its unaddressed state has no contact with any of the addressing electrodes of the matrix-addressable device. Basically a memory device of this kind is formed with a first set of parallel strip-like electrodes 1b, which in FIG. 7b is shown located on a substrate and covered by an interlayer 3b of functional material followed by a global layer of ferroelectric memory material 2, i.e. a ferroelectric polymer, which in turn is covered by a global layer 3a of functional material over which are provided another electrode set comprising likewise parallel strip-like electrodes 1a, but oriented orthogonally to the electrodes 1b, so as to form an orthogonal electrode matrix. The electrodes la can e.g. be regarded as the word lines of a matrix-addressable memory device, while the electrodes 1b can be regarded as the bit lines thereof. At the crossings between the word lines la and bit lines 1b a memory cell is defined in the matrix in the global layer of memory material 2. Thus the memory device will comprise a plurality of memory circuits C corresponding to the number of electrode crossings in the matrix. The memory circuit C is shown in more detail in cross section in FIG. 7c and here corresponds to one of the previously presented preferred embodiments of the organic electronic circuit according to the present invention. In other words the functional material 3 is provided in respective interlayers 3a, 3b which interfaces respectively electrodes 1a and 1b with the memory material 2 sandwiched therebetween. It shall be understood that a memory device of the kind shown in FIG. 7a and 7b can be provided with an insulating layer over the electrodes 1a (or a so-called separation layer) and then a second similar device can be stacked on the top thereof and so on to form a stacked or volumetric memory device as known in the prior art. It is to be understood that electrodes 1a, 1b forming the respectively word and bit lines in the memory device in FIG. 7a all will be connected with suitable driving and control and sensing circuits for performing write/read operations to the memory cells of the matrix-addressable memory device, although the peripheral external circuitry is not shown in the drawing figures.

Providing a functional material in a matrix-addressable memory device of this kind requires some attention to production detail. For instance the bit line electrodes 1b could be located on a substrate S and initially deposited as a global layer covering the substrate whereafter the electrodes are patterned e.g. in a standard photomicrolithographic process to form the strip-like bit line electrodes 1b. Alternatively parallel recesses with a cross section corresponding to an electrode 1b could be formed in the substrates and then filled with appropriately processed electrode material which if required could be planarized until the electrode top surfaces become flush with that of the substrate. In following separate steps a layer 3b of functional material could be laid down as a global layer in the memory device and then the global layer 2 of memory material is deposited before another global layer 3a of functional material is provided covering the global layer of memory material 2. Global interlayers is favourable since it provides good coverage and protection of a global layer of memory material and do not require steps of patterning which typically will increase the risk of detrimental reactions between both the electrode and the memory material and between the interlayer and the memory material. However, global layering requires non-conductivity of the interlayers, else there will be undesired interconnects between individual memory cells. This is one reason why dielectric interlayers are considered advantageous. Finally, on top of the interlayer 3a, word line electrodes la are provided as shown in FIG. 7a and possibly covered by a planarization layer with insulating and separating function. The resulting structure is of course a memory device integrating a plurality of memory circuits C according to the present invention in a passive matrix-addressable memory array.

A matrix-addressable memory device of this kind can by suitable arrangement of the external circuitry for write and read perform a write or read operation on a hugely massive parallel scale.

Now a method according to the present invention for depositing the interlayer material in a manufacturing process for memory circuits C shall be discussed in some detail.

When it is desired to minimize undesired reactions between the functional interlayer and the organic electret or ferroelectric material, a critical step is the deposition of the interlayer, especially when the interlayer is disposed on top of a layer of the organic electret or ferroelectric material. Note that deposition is less of a problem when the interlayer is disposed on a bottom electrode layer , i.e. before the presence of the organic electret or ferroelectric material. Even though an interlayer in contact with the organic electret or ferroelectric material theoretically shall have low probability to cause reactions according to the invention, this is not necessarily true during the deposition. Formation of additional and non-functional interfaces, or “dead”-layers, composed of reaction products, has to be avoided in fabrication as well. If this is not the case, such interfaces initially will affect the performance in a negative way, i.e. even before fatigue effects etc become significant. There are often high energies involved in the deposition and there are reactive methods where molecules of the interlayer material are formed in the deposition process. Using an interlayer material that is inert relative the electret or ferroelectric material may prove useless if care is not taken during the deposition process in fabrication. Thus, in conjunction with the manufacturing of circuits according to the present invention, it is advantageous to dispose the interlayer material without dissociation from a source of interlayer material to its target as a layer in the organic electronic device. The non-reactive property of a functional interlayer according to the invention will be better satisfied by depositing molecule species of the functional interlayer from a source of functional interlayer material to its target as the functional interlayer without dissociation of individual interlayer molecules.

To keep problems related to high energies at a low level, typically evaporation techniques shall be used over sputtering techniques. In the case of WO₃ as interlayer material, there are evaporants of WO₃ commercially available of high purity (99.99%). WO₃ has a melting point of 1470° C. but sublimes below that temperature, and thus a reasonable low power is required for evaporation.

In particular for WO₃, but also for ceramics in general, there are a number of various deposition techniques that may be used, for example sputtering, evaporation (thermal and e-beam), electro-deposition from solution, CVD/spray pyrolysis and sol-gel deposition by dipping, spin coating or spraying.

Embodiments and examples of materials have been presented hereinabove in order to provide concreteness to the invention and make it applicable to persons skilled in the art. It is not intended that specific references shall be considered as limitations of the scope of the invention, except from what is set forth in the accompanying claims.

1. An organic electronic circuit (C) comprising an organic electret or ferroelectric material (2) provided between a first electrode (1a) and a second electrode (1b), whereby a cell with a capacitor-like structure is defined in the organic electret or ferroelectric material and can be accessed electrically directly or indirectly via the electrodes (1a, 1b)
characterized in that at least one inorganic functional interlayer (3a; 3b) is provided between the at least one of the electrodes and the organic electret or ferroelectric material (2), ands that at least one functional interlayer (3a; 3b) is a non-conducting and substantially inert material relative to the organic electret or ferroelectric material (2) generally.

2. An organic electronic circuit (C) according to claim 1,
characterized in that the organic electronic circuit comprises a first functional interlayer (3a) provided between a first electrode (1a) and the organic electret or ferroelectric material (2), and a second functional interlayer (3b) provided between the second electrode (1b) and the organic electret or ferroelectric material (2).

3. An organic electronic circuit (C) according to claim 1,
characterized in that at least one additional functional interlayer (4a; 4b) of another functional interlayer material provided between at least one of the electrodes (1a; 1b) and the organic electret or ferroelectric material (2).

4. An organic electronic circuit (C) according to claim 1,
characterized in that at least one functional interlayer (3a; 3b) is adapted to participate in a specific chemical reaction or bonding with one or more constituents of the adjoining electret or ferroelectric material (2), or one or more reactive species generated therein in course of the circuit's operation.

5. An organic electronic circuit (C) according to claim 1,
characterized in that at least one functional interlayer (3a; 3b) is provided as a global layer provided between a global layer of the organic electret or ferroelectric material (2) and the first or second electrode means (1a; 1b).

6. An organic electronic circuit (C) according to claim 1,
characterized in that the functional interlayer material is a ceramic material.

7. An organic electronic circuit (C) according to claim 6,
characterized in that the functional interlayer material is a ternary ceramic material.

8. An organic electronic circuit (C) according to claim 6,
characterized in that the functional interlayer material is a binary or ternary ceramic material that contains a metal with a high oxidation number.

9. An organic electronic circuit (C) according to claim 6,
characterized in that the functional interlayer material is a metal oxide.

10. An organic electronic circuit (C) according to claim 9,
characterized in that the functional interlayer material is selected as one or more of the following, viz. tungsten oxide, tantalum oxide, molybdenum oxide, vanadium oxide, niobium oxide or titanium oxide.

11. An organic electronic circuit (C) according to claim 1,
characterized in that the organic electret or ferroelectric material (2) consists of single molecules, oligomers, homopolymers, copolymers, or blends or compounds thereof.

12. An organic electronic circuit (C) according to claim 1,
characterized in that the organic electret or ferroelectric material (2) contains fluorine.

13. An organic electronic circuit (C) according to claim 1,
characterized in that organic electret or ferroelectric material (2) is selected as one or more of the following, viz. polyvinylidene fluoride (PVDF), polyvinylidene with any of its copolymers, ter-polymers based on either copolymers or PVDF-trifluoroethylene (P(VDF-TrFE)), odd-numbered nylons, odd-numbered nylons with any of their copolymers, cyanopolymers, and cyanopolymers with any of their copolymers.

14. An organic electronic circuit (C) according to claim 1,
characterized in that the electrode material is selected as one of the following materials, viz. aluminum, platinum, gold, titanium, copper, palladium or conducting alloys or composites thereof.

15. An organic electronic circuit (C) according to claim 1,
characterized in that a plurality of such circuits (C) forms memory circuits of a matrix-addressable array, that the cells of the memory circuits (C) form distinct portions in a global thin-film layer of the organic electret or ferroelectric material (2), that the first and second electrodes (1a; 1b) form portions of first and second electrode means respectively, each electrode means comprising a plurality of parallel strip-like electrodes (1a; 1b) wherein the electrodes (1b) of the second electrode means are oriented at an angle, preferably orthogonally, to the electrodes (1a) of the first electrode means, and that the organic electret or ferroelectric global thin-film layer (2) is sandwiched therebetween, such that the memory cells of the memory circuits (C) are defined in the thin-film global layer (2) at the crossings of respectively the electrodes (1a) of the first electrode means and the electrodes (1b) of the second electrode means, whereby the array of memory circuits (C) is formed by the electrode means and the global layer (2) of the memory material, the memory cells realizing an integrated passive matrix-addressable electret or ferroelectric memory device wherein the addressing of respective memory cells for write and read operations take place via the electrodes (1a, 1b) in suitable connection with external circuitry for driving, control and detection.

16. A method for manufacturing an organic electronic circuit comprising
an organic electret or ferroelectric material provided between a first electrode (1a) and a second electrode (1b) and at least one first inorganic interlayer (3a; 3b) one of the electrodes (1a; 1b) and the organic electret or ferroelectric material, a functional interlayer located between the electrode and the electro-active organic material,
characterized by depositing molecular species for the functional interlayer (3a, 3b) from a source of functional interlayer material without dissociation of individual molecules forming the functional interlayer (3a, 3b).

17. A method according to claim 16,
characterized by depositing the functional interlayer (3a, 3b) by one of the following processes, viz. sputtering, electron beam evaporation, thermal evaporation, electro-deposition from solution, sol-gel deposition by dipping, sol-gel deposition by spin coating, or sol-gel deposition by spraying.

18. A method according to claim 16,
characterized by depositing tungsten oxide as the functional interlayer by evaporation and using WO₃ as the evaporant.
